(19) United States
(12) Patent Application Publication
(10) Pub. No.: US 2024/0431073 A1
(43) Pub. Date: Dec. 26, 2024

(54) CHASSIS, ELECTRONIC APPARATUS AND CHASSIS EXHAUST METHOD

(71) Applicant: BITMAIN TECHNOLOGIES INC., Beijing (CN)

(72) Inventors: Ketuan ZHAN, Beijing (CN); Hongbo Zeng, Beijing (CN); Cheng Li, Beijing (CN); Mingliang Hao, Beijing (CN); Hangkong Hu, Beijing (CN); Yang Li, Beijing (CN); Yongbo Ge, Beijing (CN); Haicai LV, Beijing (CN); Te Pi, Beijing (CN)

(21) Appl. No.: 18/830,474

(22) Filed: Sep. 10, 2024

Related U.S. Application Data
(63) Continuation of application No. PCT/CN2023/074663, filed on Feb. 6, 2023.

(30) Foreign Application Priority Data
Mar. 10, 2022 (CN) 202210231597.5

(51) Int. Cl. H05K 7/20

(52) U.S. Cl. CPC H05K 7/203; H05K 7/20318; H05K 7/20327; H05K 7/20409

(57) ABSTRACT

The present disclosure relates to a chassis, an electronic apparatus and a chassis exhaust method. The chassis includes: a housing, forming an accommodating cavity, where the accommodating cavity is configured for accommodating cooling liquid and a heating component immersed in the cooling liquid; a condenser, disposed in the accommodating cavity and configured for condensing the cooling liquid in a gas phase; a cooling liquid interface, disposed on the housing; and an exhaust component, located on the housing and at least configured for exhausting gas in the accommodating cavity when the cooling liquid is injected into the accommodating cavity through the cooling liquid interface.

### CROSS-REFERENCE TO RELATED APPLICATION

This application is a continuation of International Application No. PCT/CN2023/074663, filed on Feb. 6, 2023, which claims priority to Chinese Patent Application No. 202210231597.5, filed on Mar. 10, 2022. The disclosures of the aforementioned applications are hereby incorporated by reference in their entireties.

### TECHNICAL FIELD

The present disclosure relates to the technical field of immersion liquid cooling, and specifically relates to a chassis, an electronic apparatus and a chassis exhaust method.

### BACKGROUND

Integrated circuit devices which perform high-speed operations in a supercomputing apparatus, such as application specific integrated circuit (ASIC, Application Specific Integrated Circuit) chips, generate a large amount of heat when working. When the heat accumulates to a certain degree, the temperature of the integrated circuit devices rises, so that the working capability of the integrated circuit devices is reduced, and even the integrated circuit devices are burned.

Generally, heat dissipation may be performed on the integrated circuit device by using a heat sink or the like, for example, the heat sink is closely attached to the integrated circuit device, and heat dissipation is performed by a fan or a liquid cooling tube on the heat sink. With the continuous improvement of the computing capability of integrated circuit devices (such as ASIC and the like), the generated heat becomes larger and larger, and the existing heat dissipation manner cannot meet the working of integrated circuit devices. Therefore, how to dissipate heat of the integrated circuit devices and meet the cooling requirements of the apparatus is a problem to be solved urgently.

### SUMMARY

Embodiments of the present disclosure provides a chassis, an electronic apparatus and a chassis exhaust method.

In a first aspect according to the embodiments of the present disclosure, a chassis is provided, the chassis includes:
a housing, forming an accommodating cavity, where the accommodating cavity is configured for accommodating cooling liquid and a heating component immersed in the cooling liquid;
a condenser, disposed in the accommodating cavity and configured for condensing the cooling liquid in a gas phase;
a cooling liquid interface, disposed on the housing; and
an exhaust component, located on the housing and at least configured for exhausting gas in the accommodating cavity when the cooling liquid is injected into the accommodating cavity through the cooling liquid interface.

In an embodiment, the condenser includes a condenser tube, and an inner wall and/or an outer wall of the condenser tube are provided with a rib-like protrusion.

In an embodiment, the rib-like protrusion is spirally disposed on the inner wall and/or the outer wall of the condenser tube.

In an embodiment, a cross section of the rib-like protrusion is V-shaped or U-shaped.

In an embodiment, a condensate liquid is provided in the condenser, and the condenser includes: a liquid inlet disposed on the housing for the condensate liquid to flow in, and a liquid outlet disposed on the housing for the condensate liquid to flow out;
the liquid inlet is communicated with an external heat exchange device;
the liquid outlet is communicated with the heat exchange device.

In an embodiment, the condenser is in contact with an inner wall of a top of the housing.

In an embodiment, the housing includes a first housing and a second housing, where the first housing hermetically covers the second housing to form the accommodating cavity.

In an embodiment, the exhaust component includes a one-way valve and a ball valve.

In a second aspect according to the embodiments of the present disclosure, an electronic apparatus is provided, including:
the chassis according to the first aspect;
the cooling liquid, accommodated in the accommodating cavity formed by the housing of the chassis; and
the heating component, immersed in the cooling liquid, where the heating component includes at least one computing board.

In an embodiment, a first surface of the computing board faces towards a top of the housing, and an angle between the first surface and a vertical direction is greater than 0 degree and less than 90 degrees, where the first surface is provided with an integrated circuit device which generates heat.

In an embodiment, the integrated circuit device includes a matrix-arranged chipset.

In an embodiment, the angle between the first surface and the vertical direction is greater than or equal to 5 degrees, and less than or equal to 85 degrees.

In an embodiment, the angle between the first surface and the vertical direction is 20 degrees.

In an embodiment, a chip surface of a chip of the integrated circuit device, which is facing away from the first surface, is provided with a metal pore layer, where the metal pore layer includes metal particles and pores between the metal particles.

In an embodiment, a metal packaging housing of the chip is disposed between the chip surface and the metal pore layer;
or,
a thermal conductive coating is disposed between the chip surface and the metal pore layer.

In an embodiment, the thermal conductive coating includes a metal thermal conductive coating or a non-metal thermal conductive coating.

In an embodiment, the heating component includes a power supply component of the electronic apparatus and/or a control board of the electronic apparatus.

In an embodiment, the electronic apparatus further includes an external heating component disposed on an external surface of the housing.

In an embodiment, the cooling liquid includes a fluorinated liquid.

In a third aspect according to the embodiments of the present disclosure, a chassis exhaust method is provided, which is applied to the electronic apparatus according to the second aspect, the method includes:
when a first liquid-surface position of the cooling liquid in the accommodating cavity which is formed by the housing of the chassis of the electronic apparatus, is lower than that of the condenser, configuring the condenser for condensing gas in the accommodating cavity to a first temperature; and
injecting the cooling liquid into the accommodating cavity through the cooling liquid interface to a second liquid-surface position, and exhausting the gas in the accommodating cavity through the exhaust component, where the second liquid-surface position is higher than the first liquid-surface position.

In an embodiment, before the configuring the condenser for condensing gas in the accommodating cavity to the first temperature, the method further includes:
heating the cooling liquid to a second temperature by configuring the heating component immersed in the cooling liquid, where the second temperature is higher than the first temperature.

In an embodiment, the second temperature is greater than or equal to a phase-change temperature of the cooling liquid.

In an embodiment, the method further includes:
discharging the cooling liquid from the accommodating cavity through the cooling liquid interface to a third liquid-surface position, where the third liquid-surface position is lower than the second liquid-surface position and higher than the first liquid-surface position; and
injecting the cooling liquid into the accommodating cavity through the cooling liquid interface to the second liquid-surface position, and exhausting the gas in the accommodating cavity through the exhaust component.

In an embodiment, the second liquid-surface position is a liquid-surface position when the accommodating cavity is filled with the cooling liquid.

In an embodiment, the first liquid-surface position is higher than that of a heating component.

According to the chassis, the electronic apparatus and the chassis exhaust method provided by the embodiments of the present disclosure, the chassis includes: a housing, forming an accommodating cavity, where the accommodating cavity is configured for accommodating cooling liquid and a heating component immersed in the cooling liquid; a condenser, disposed in the accommodating cavity and configured for condensing the cooling liquid in a gas phase; a cooling liquid interface, disposed on the housing; an exhaust component, located on the housing and at least configured for exhausting gas in the accommodating cavity when the cooling liquid is injected into the accommodating cavity through the cooling liquid interface. In this way, by disposing the exhaust component which exhausts the gas in the accommodating cavity when the cooling liquid is injected through the cooling liquid interface, the gas (such as air or the like) with a poor heat exchange capability in a phase-change heat dissipation process is exhausted, thereby improving the working efficiency of the condenser, and further improving the heat dissipation effect of the chassis.

It should be understood that the foregoing general description and the following detailed description are merely exemplary and explanatory, and cannot limit the present disclosure.

### BRIEF DESCRIPTION OF DRAWINGS

The accompanying drawings, which are incorporated herein and constitute a part of the specification, illustrate embodiments consistent with the present disclosure, and together with the specification, serve to explain the principles of the disclosure.

FIG. 1 is a schematic structural diagram of a chassis according to an exemplary embodiment.

FIG. 2 is a schematic structural diagram of an exhaust component according to an exemplary embodiment.

FIG. 3 is a schematic structural diagram of a condenser according to an exemplary embodiment.

FIG. 4 is a schematic diagram of the direction A of the chassis according to an exemplary embodiment.

FIG. 5 is a schematic structural diagram of a computing board according to an exemplary embodiment.

FIG. 6 is a schematic diagram of a cross-sectional structure of a condenser tube according to an exemplary embodiment.

FIG. 7 is a flowchart of an exhaust method according to an exemplary embodiment.

### DESCRIPTION OF EMBODIMENTS

Here, exemplary embodiments would be described in detail, examples of which are illustrated in the accompanying drawings. When the following description refers to the accompanying drawings, unless otherwise indicated, the same numbers in different drawings indicate the same or similar elements. The embodiments described in the following exemplary embodiments do not represent all embodiments consistent with the present disclosure. Rather, they are merely examples of devices consistent with some aspects of the present disclosure, as detailed in the appended claims.

In the description of the present disclosure, it should be understood that the orientation or position relationships indicated by the terms “longitudinal”, “lateral”, “length”, “width”, “thickness”, “upper”, “lower”, “front”, “back”, “left”, “right”, “inner”, “outer”, etc. are based on the orientation or position relationships shown in the accompanying drawings. It is only for the convenience in describing the present disclosure and simplifying the description, rather than indicating or implying that the indicated device or element must have a particular orientation, be constructed and operated in a particular orientation. Therefore, the present disclosure cannot be construed as being limited thereto.

In the description of the present disclosure, “a plurality of” means two or more, and “several” means one or more.

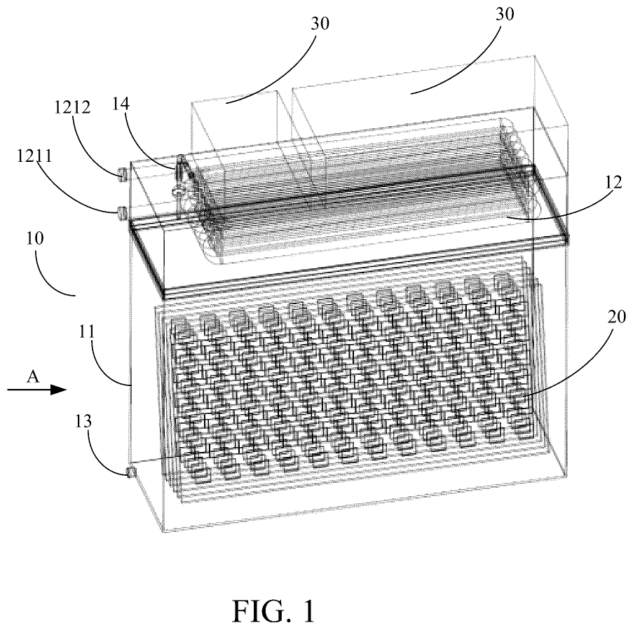

In an embodiment of the present disclosure, as shown in FIG. 1, a chassis 10 is provided. The chassis 10 includes:
a housing 11, forming an accommodating cavity, where the accommodating cavity is configured for accommodating cooling liquid and a heating component 20 immersed in the cooling liquid;
a condenser 12, disposed in the accommodating cavity and configured for condensing the cooling liquid in a gas phase;
a cooling liquid interface 13, disposed on the housing 11;
an exhaust component 14, located on the housing 11 and at least configured for exhausting gas in the accommodating cavity when the cooling liquid is injected into the accommodating cavity through the cooling liquid interface 13.

Here, the chassis 10 may be applied to electronic apparatuses with high computing capabilities, such as computers, servers, supercomputing apparatuses, etc. The chassis 10 may be configured for disposing the heating component 20 of the electronic apparatus.

The heating component 20 may include a printed circuit board having an integrated circuit device (such as a processor or the like). For example, the chassis 10 may be configured for disposing a computing board of the supercomputing apparatus. One or more computing boards may be disposed in the accommodating cavity.

In an embodiment, the heating component 20 includes a power supply component of the electronic apparatus and/or a control board of the electronic apparatus.

The electronic apparatus with high computing capabilities generally includes the computing board, the power supply component that provides power for the computing board, and the control board that coordinates the work of the computing board. The power supply component and the control board also generate heat. The power supply component and the control board may also be immersed in the cooling liquid to dissipate heat.

The housing 11 of the chassis 10 may be made of metal or non-metal materials, and the housing forms an accommodating cavity. The heating component 20 may be disposed at a lower part of the accommodating cavity.

The heating component 20 may be immersed in the cooling liquid, and the heating component 20 may exchange heat with the cooling liquid to conduct the generated heat to the cooling liquid, thereby reducing its temperature.

The cooling liquid produces phase-change after absorbing heat, and is converted from liquid phase into gas phase, that is, the cooling liquid is converted from liquid into vapor after absorbing heat. In a process of converting from the liquid phase into the gas phase, the cooling liquid absorbs the heat generated by the heating component 20. A position of the accommodating cavity where the cooling liquid is located may be referred to an immersion section.

An upper part of the accommodating cavity may be provided with the condenser 12, which is configured for condensing the cooling liquid in the gas phase, so that the cooling liquid is converted from the gas phase into the liquid phase. In a process of converting from the gas phase into the liquid phase, the cooling liquid releases heat to the condenser 12, and the condenser 12 exchanges the absorbed heat with the external environment, thereby completing a heat dissipation process of the heating component 20. A position of the accommodating cavity where the condenser 12 is located may be referred to a condensation section.

In an embodiment, the cooling liquid includes a fluorinated liquid.

The cooling liquid may be the fluorinated liquid or the like. The boiling point of the fluorinated liquid is 40° C. to 65° C. at the atmospheric pressure. The cooling liquid may be selected according to a chip-temperature control condition, ensuring that an operating temperature in the housing 11 in the working state is close to that of the external environment, so that the operating temperature in the housing 11 in the working state can not reach the boiling point of the cooling liquid, thereby preventing the cooling liquid in the housing 11 from vaporizing into cooling liquid gas due to boiling, and effectively avoiding the leakage of cooling liquid gas.

A predetermined spacing distance is provided between a bottom of the condenser 12 and a liquid surface of the cooling liquid, that is, a bubble breaking section. In the heat dissipation process of the heating component 20, the bubble breaking section is configured for bubbles which are generated after the cooling liquid is heated, to rise to the liquid surface of the cooling liquid and then break up to generate droplets and vapor. The droplets directly drop into the immersion section under the gravity. The vapor rises in the bubble breaking section and enters the condensation section which are communicated with the bubble breaking section, and is condensed by the condenser 12. The predetermined spacing distance may be 10 cm to 100 cm.

The cooling liquid interface 13 may be disposed at a lower part of the housing, so that more cooling liquid may be discharged during the process of discharging the cooling liquid. For example, the cooling liquid interface 13 may be disposed at a bottom of the housing, so that the cooling liquid may be completely discharged.

For the convenience of operation, the heating component 20 may be disposed in the accommodating cavity firstly, and then the cooling fluid is injected into the accommodating cavity through the cooling liquid interface 13. With the injection of the cooling liquid, the pressure in the accommodating cavity increases. The gas in the accommodating cavity, such as air, cooling liquid vapor, or a mixed gas of the air and the cooling liquid vapor, may be exhausted out of the accommodating cavity through the exhaust component 14.

Because the gas is located above the cooling liquid, the exhaust component 14 may be disposed at a top of the accommodating cavity. The exhaust component 14 may be a component, such as a valve or the like. It may be opened when the gas needs to be exhausted outward, and closed after the gas is exhausted.

In an embodiment, the exhaust component 14 may be a passive exhaust component 14, that is, the exhaust component 14 itself does not consume energy to drive the gas, but exhausts through a pressure difference between the inside and outside of the accommodating cavity.

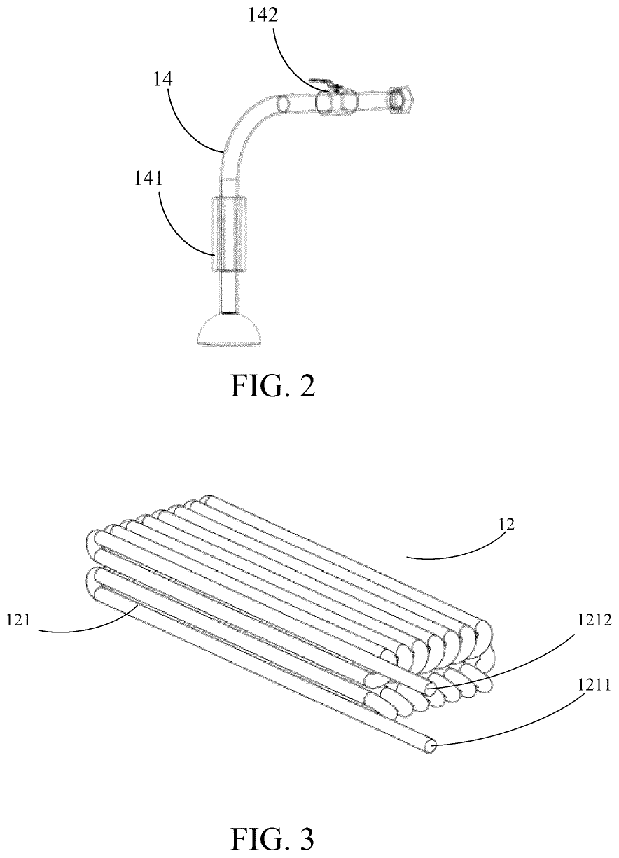

In an embodiment, as shown in FIG. 2, the exhaust component 14 includes a one-way valve 141 and a ball valve 142.

On a gas exhaust path, the one-way valve 141 (also referred to a check valve) may be disposed in front of the ball valve 142. The one-way valve 141 may be configured for preventing external air from reversely entering the accommodating cavity when the pressure in the accommodating cavity is lower than the pressure of the external air. The ball valve 142 may be configured for controlling the on-off of the gas exhaust path.

During a process of normal-pressure assembly and injection of the cooling liquid, there is a certain amount of air in the accommodating cavity. Since the air does not produce phase-change within a working-temperature-range of the cooling liquid, it has a relatively low effect on the heat dissipation process. On the contrary, the working efficiency of the condenser 12 is reduced due to the existence of the air, causing that two-phase operating temperature rises, and the operating pressure increases, so that the structure of the chassis 10 is damaged, thereby generating leakage, etc.

Therefore, when the cooling liquid is injected, the whole accommodating cavity may be filled with the cooling liquid, and all the gas is exhausted through the exhaust component 14. Therefore, the air in the accommodating cavity in the working state is reduced, and the working efficiency of the condenser 12 is improved, thereby improving the heat dissipation effect of the chassis 10.

In this way, by disposing the exhaust component 14 which exhausts the gas in the accommodating cavity when the cooling liquid is injected through the cooling liquid interface 13, the gas (such as air or the like) with a poor heat exchange capability in a phase-change heat dissipation process is exhausted, thereby improving the working efficiency of the condenser 12, and further improving the heat dissipation effect of the chassis 10.

In an embodiment, as shown in FIG. 3, the condenser 12 includes a condenser tube 121, and an inner wall and/or an outer wall of the condenser tube 121 are provided with a rib-like protrusion.

Here, the condenser 12 may include the condenser tube 121 disposed above the liquid surface of the cooling liquid. A condensate liquid flows in the condenser tube 121.

The cooling liquid releases heat to a tube wall of the condenser tube 121 in the process of converting from the gas phase into the liquid phase. The condensate liquid flowing through the condenser tube 121 may have a relatively low temperature. The condensate liquid performs heat exchange with the tube wall of the condenser tube 121 which has a relatively high temperature, thereby reducing the temperature of the tube wall of the condenser tube 121 and improving the effect of condensing the cooling liquid.

The condensate liquid includes, but is not limited to, water, ethanol, electronic fluorinated liquid, and/or mineral oil, or the like.

The condenser tube 121 may be horizontally arranged in one or more rows. The condenser tube 121 may be arranged in an S-shape, or may be arranged in a disc shape, which is not limited herein.

The inner wall and/or the outer wall of the condenser tube 121 are provided with the rib-like protrusions. The rib-like protrusion of the inner wall may increase a surface area of the inner wall of the condenser tube 121, and improve the heat exchange efficiency between the condensate liquid and the condenser tube 121. The rib-like protrusion of the outer wall may improve a surface area of the outer wall of the condenser tube 121, and improve the heat exchange efficiency between the cooling liquid and the condenser tube 121, thereby improving the phase-change efficiency of the cooling liquid, and thereby improving the heat dissipation effect.

In an embodiment, a height of the rib-like protrusion is of 0.1 mm to 5 mm.

In an embodiment, the condenser 12 is in contact with an inner wall of a top of the housing 11.

In an embodiment, the electronic apparatus further includes an external heating component 30 disposed on an external surface of the housing 11.

The external heating component 30 may include a power supply component of the electronic apparatus and/or a control board of the electronic apparatus.

A top row of a plurality of rows of the condenser tubes 121 may be in direct contact with the top of the housing 11. The top of the housing 11 may be configured for placing the external heating component 30, such as the power supply component in the electronic apparatus and/or the control board of the electronic apparatus. A heating component 20 which is not suitable to be immersed in the cooling liquid, may be disposed at the top of the housing 11.

In an embodiment, the rib-like protrusion is spirally disposed on the inner wall and/or the outer wall of the condenser tube 121.

The rib-like protrusion is arranged in a spiral manner, which may further improve the surface area of the inner wall and/or the outer wall, and improve the heat exchange efficiency between the condensate liquid and the condenser tube 121, and/or between the cooling liquid and the condenser tube 121, thereby improving the phase-change efficiency of the cooling liquid, and thereby improving the heat dissipation effect.

In an embodiment, a cross section of the rib-like protrusion is V-shaped or U-shaped.

The cooling liquid in the gas phase is easier to be phase-changed into the liquid phase at a tip, therefore, the cross section of the rib-like protrusion may be set to be V-shaped or U-shaped. In this way, the phase-change efficiency of the cooling liquid at a tip of the rib-like protrusion may be promoted, thereby improving the heat dissipation effect.

In an embodiment, a condensate liquid is provided in the condenser 12, and the condenser 12 includes: a liquid inlet 1211 disposed on the housing 11 for the condensate liquid to flow in, and a liquid outlet 1212 disposed on the housing 11 for the condensate liquid to flow out;
the liquid inlet 1211 is communicated with an external heat exchange device;
the liquid outlet 1212 is communicated with the heat exchange device.

An outer wall of the housing 11 may be provided with the liquid inlet 1211 and the liquid outlet 1212. The condensate liquid in the condenser tube 121 flows to the heat exchange device to exchange heat with the external environment. The condensate liquid may flow into the condenser tube 121 from the liquid inlet 1211 from the outside, and after completing the heat exchange in the housing 11, flow out of the liquid outlet 1212 and flow into the heat exchange device.

The heat exchange device is configured for performing heat exchange between the condensate liquid and the external environment, and reducing the temperature of the condensate liquid which flows out of the condenser tube 121, and re-flowing the cooled condensate liquid into the condenser tube 121 from the liquid inlet 1211.

Exemplarily, the heat exchange device may include a first pipe which is connected with the liquid inlet 1211, and a second pipe which is connected with the liquid outlet 1212. The heat exchange device may include a radiating fin and a radiating fan to dissipate heat of the condensate liquid which flows through the heat exchange device.

In an embodiment, the housing 11 includes a first housing and a second housing, where the first housing hermetically covers the second housing to form the accommodating cavity.

The first housing and the second housing may be sealed in a form of a sealing ring and sealant. The first housing may be a housing cover located at an upper part, and the second housing may be a housing bottom located at a lower part.

In an embodiment, the condenser 12 may be disposed in the first housing, and the heating component 20 may be disposed in the second housing, which is convenient to maintain the condenser 12 and the heating component 20 separately when the first housing and the second housing are separated.

In an embodiment of the present disclosure, as shown in FIG. 1, an electronic apparatus is provided. The electronic apparatus includes:
the chassis 10 shown in FIG. 1; the cooling liquid, accommodated in the accommodating cavity formed by the housing 11 of the chassis 10; the heating component 20, immersed in the cooling liquid, where the heating component 20 includes at least one computing board 21.

As shown in FIG. 1, the chassis 10 includes:
a housing 11, forming an accommodating cavity, where the accommodating cavity is configured for accommodating a cooling liquid and a heating component 20 immersed in the cooling liquid;
a condenser 12, disposed in the accommodating cavity and configured for condensing the cooling liquid in a gas phase;
a cooling liquid interface 13, disposed on the housing 11;
an exhaust component 14, located on the housing 11 and at least configured for exhausting gas in the accommodating cavity when the cooling liquid is injected into the accommodating cavity through the cooling liquid interface 13.

Here, the chassis 10 may be applied to electronic apparatuses with high computing capabilities, such as computers, servers, supercomputing apparatuses, etc. The chassis 10 may be configured for disposing the heating component 20 of the electronic apparatus.

The heating component 20 may include a printed circuit board having an integrated circuit device (such as a processor or the like). For example, the chassis 10 may be configured for disposing a computing board 21 of the supercomputing apparatus. One or more computing boards 21 may be disposed in the accommodating cavity.

In an embodiment, the heating component 20 includes a power supply component of the electronic apparatus and/or a control board of the electronic apparatus.

The electronic apparatus with high computing capabilities generally includes the computing board 21, the power supply component that provides power for the computing board 21, and the control board that coordinates the work of the computing board 21. The power supply component and the control board also generate heat. The power supply component and the control board may also be immersed in the cooling liquid to dissipate heat.

The housing 11 of the chassis 10 may be made of metal or non-metal materials, and the housing forms an accommodating cavity. The heating component 20 may be disposed at a lower part of the accommodating cavity.

The heating component 20 may be immersed in the cooling liquid, and the heating component 20 may exchange heat with the cooling liquid to conduct the generated heat to the cooling liquid, thereby reducing its temperature.

The cooling liquid produces phase-change after absorbing heat, and is converted from liquid phase into gas phase, that is, the cooling liquid is converted from liquid into vapor after absorbing heat. In a process of converting from the liquid phase into the gas phase, the cooling liquid absorbs the heat generated by the heating component 20. A position of the accommodating cavity where the cooling liquid is located may be referred to an immersion section.

An upper part of the accommodating cavity may be provided with the condenser 12, which is configured for condensing the cooling liquid in the gas phase, so that the cooling liquid is converted from the gas phase into the liquid phase. In a process of converting from the gas phase into the liquid phase, the cooling liquid releases heat to the condenser 12, and the condenser 12 exchanges the absorbed heat with the external environment, thereby completing a heat dissipation process of the heating component 20.

A position of the accommodating cavity where the condenser 12 is located may be referred to a condensation section.

In an embodiment, the cooling liquid includes a fluorinated liquid.

The cooling liquid may be the fluorinated liquid or the like. The boiling point of the fluorinated liquid is 40° C. to 65° C. at the atmospheric pressure. The cooling liquid may be selected according to a chip-temperature control condition, ensuring that an operating temperature in the housing 11 in the working state is close to that of the external environment, so that the operating temperature in the housing 11 in the working state can not reach the boiling point of the cooling liquid, thereby preventing the cooling liquid in the housing 11 from vaporizing into cooling liquid gas due to boiling, and effectively avoiding the leakage of cooling liquid gas.

A predetermined spacing distance is provided between a bottom of the condenser 12 and a liquid surface of the cooling liquid, that is, a bubble breaking section. In the heat dissipation process of the heating component 20, the bubble breaking section is configured for bubbles which are generated after the cooling liquid is heated, to rise to the liquid surface of the cooling liquid and then break up to generate droplets and vapor. The droplets directly drop into the immersion section under the gravity. The vapor rises in the bubble breaking section and enters the condensation section which are communicated with the bubble breaking section, and is condensed by the condenser 12. The predetermined spacing distance may be 10 cm to 100 cm.

The cooling liquid interface 13 may be disposed at a lower part of the housing, so that more cooling liquid may be discharged during the process of discharging the cooling liquid. For example, the cooling liquid interface 13 may be disposed at a bottom of the housing, so that the cooling liquid may be completely discharged.

For the convenience of operation, the heating component 20 may be disposed in the accommodating cavity firstly, and then the cooling fluid is injected into the accommodating cavity through the cooling liquid interface 13. With the injection of the cooling liquid, the pressure in the accommodating cavity increases. The gas in the accommodating cavity, such as air, cooling liquid vapor, or a mixed gas of the air and the cooling liquid vapor, may be exhausted out of the accommodating cavity through the exhaust component 14.

Because the gas is located above the cooling liquid, the exhaust component 14 may be disposed at a top of the accommodating cavity. The exhaust component 14 may be a component, such as a valve or the like. It may be opened when the gas needs to be exhausted outward, and closed after the gas is exhausted.

In an embodiment, the exhaust component 14 may be a passive exhaust component 14, that is, the exhaust component 14 itself does not consume energy to drive the gas, but exhausts through a pressure difference between the inside and outside of the accommodating cavity.

In an embodiment, as shown in FIG. 2, the exhaust component 14 includes a one-way valve 141 and a ball valve 142.

On a gas exhaust path, the one-way valve 141 (also referred to a check valve) may be disposed in front of the ball valve 142. The one-way valve 141 may be configured for preventing external air from reversely entering the accommodating cavity when the pressure in the accommodating cavity is lower than the pressure of the external air. The ball valve 142 may be configured for controlling the on-off of the gas exhaust path.

During a process of normal-pressure assembly and injection of the cooling liquid, there is a certain amount of air in the accommodating cavity. Since the air does not produce phase-change within a working-temperature-range of the cooling liquid, it has a relatively low effect on the heat dissipation process. On the contrary, the working efficiency of the condenser 12 is reduced due to the existence of the air, causing that two-phase operating temperature rises, and the operating pressure increases, so that the structure of the chassis 10 is damaged, thereby generating leakage, etc.

Therefore, when the cooling liquid is injected, the whole accommodating cavity may be filled with the cooling liquid, and all the gas is exhausted through the exhaust component 14. Therefore, the air in the accommodating cavity in the working state is reduced, and the working efficiency of the condenser 12 is improved, thereby improving the heat dissipation effect of the chassis 10.

In this way, by disposing the exhaust component 14 which exhausts the gas in the accommodating cavity when the cooling liquid is injected through the cooling liquid interface 13, the gas (such as air or the like) with a poor heat exchange capability in a phase-change heat dissipation process is exhausted, thereby improving the working efficiency of the condenser 12, and further improving the heat dissipation effect of the chassis 10.

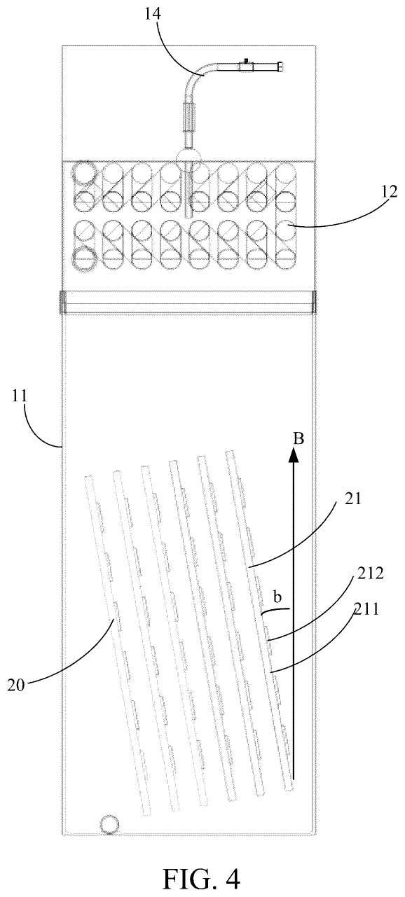

In an embodiment, as shown in FIG. 4, a first surface 211 of the computing board 21 faces towards a top of the housing 11, and an angle between the first surface 211 and a vertical direction is greater than 0 degree and less than 90 degrees, where the first surface 211 is provided with an integrated circuit device which generates heat.

FIG. 4 is a view of FIG. 1 in direction A. As shown in FIG. 4, a direction indicated by arrow B is a vertical direction, and angle b between the first surface 211 and the vertical direction is greater than 0 degree and less than 90 degrees.

The first surface 211 faces towards the top of the housing 11, that is, the first surface 211 faces towards a rising direction of the cooling liquid bubbles. With respect to the vertical direction, the computing board 21 may be obliquely arranged.

In an embodiment, a plurality of computing boards 21 may be arranged in parallel.

In the immersion section, the plurality of computing boards 21 which may be stacked and arranged in parallel, are immersed in the cooling liquid, and a spacing between adjacent computing boards 21 is 8 mm to 20 mm. The liquid surface of the cooling liquid is about 5 mm to 55 mm higher than a top of the computing board 21, ensuring that all the computing boards 21 are immersed in the cooling liquid during a process of two-phase immersion heat exchange.

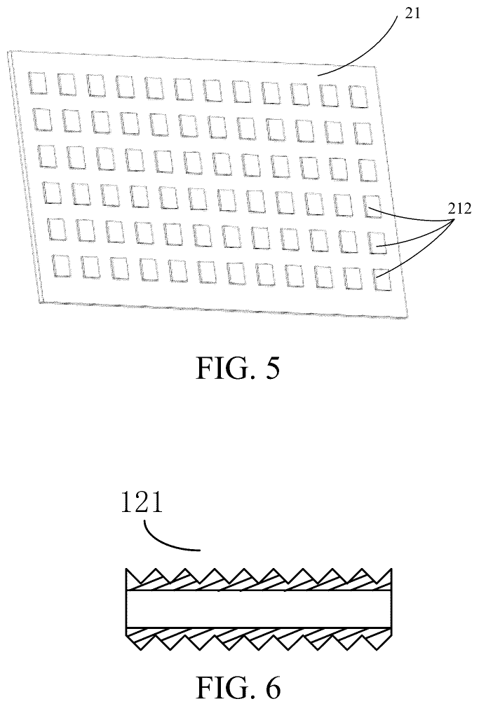

In an embodiment, as shown in FIG. 5, the integrated circuit device includes a matrix-arranged chipset 212.

A plurality of rows of integrated circuit devices are arranged in parallel on the computing board 21 to form the matrix-arranged chipset 212. The matrix-arranged chipset 212 has characteristics of small volume, high heat-flux-density, matrix arrangement and large total power. In the working process, a large amount of heat is generated. The cooling liquid is heated on a surface of the integrated circuit device, and bubbles are generated on the surface of the integrated circuit device.

If the computing board 21 is vertically arranged, since bubbles are vertically floating, in the matrix-arranged integrated circuit devices, bubbles which are generated on the surface of the lower integrated circuit device, may be close to the surface of the upper integrated circuit device in a floating process, thereby occupying a space of the cooling liquid of the surface of the upper integrated circuit device. That is, a proportion of the dielectric film of the surface of the upper integrated circuit device is increased, thereby reducing the heat exchange capability of the surface of the upper integrated circuit device, and resulting in poor heat dissipation.

If the computing board 21 is horizontally arranged, the surface of the integrated circuit device faces towards the rising direction of the bubbles. An edge position of the surface of the integrated circuit device may be supplemented with the cooling liquid in time. However, because there are bubbles rising around, a middle position of the surface of the integrated circuit device may not be supplemented with the cooling liquid in time. Similarly, the proportion of the dielectric film of the middle position of the surface of the integrated circuit device is increased, thereby reducing the heat exchange capability of the surface of the integrated circuit device, and resulting in poor heat dissipation.

Therefore, the computing board 21 may be obliquely arranged. In the matrix-arranged integrated circuit devices, bubbles which are generated on the surface of the lower integrated circuit device, move vertically upward under the action of floatation. Due to the inclination of the computing board 21, the bubbles sweep past a certain distance away from the surface of the upper integrated circuit device, thereby reducing the situation where the rising bubbles are close to the surface of the upper integrated circuit device, and thereby reducing the proportion of the dielectric film of the surface of the upper integrated circuit device. With respect to the situation where the computing board 21 is vertically arranged, the heat exchange capacity of the surface of the upper integrated circuit device is improved. Further, disturbance is generated in a rising process of bubbles, which accelerates a process of generation and separation of bubbles of the surface of the upper integrated circuit device, and improves heat-transfer temperature difference and heat-transfer coefficient of modal condensation, and further improves the heat exchange capability of the surface of the upper integrated circuit device.

In an embodiment, the angle between the first surface 211 and the vertical direction is greater than or equal to 5 degrees, and less than or equal to 85 degrees.

In an embodiment, the angle between the first surface 211 and the vertical direction is 20 degrees.

In an embodiment, an angle of 20 degrees may be used, and it may be achieved that the critical heat flux density reaches 50 W/cm² to 500 W/cm².

In an embodiment, a chip surface of a chip of the integrated circuit device, which is facing away from the first surface 211, is provided with a metal pore layer, where the metal pore layer includes metal particles and pores between the metal particles.

The chip surface of the chip of the integrated circuit device, which is facing away from the first surface 211, is a surface of the integrated circuit device which is in contact with the cooling liquid and generates bubbles. The chip surface conducts heat to the metal pore layer through heat conduction. The metal particles in the metal pore layer have good thermal conductivity. A pore structure may provide a vaporization core for boiling-and-heat-exchange of the cooling liquid. Therefore, the heat conversion efficiency is improved, further improving the heat dissipation effect of the chassis 10.

Exemplarily, a thickness of the metal pore layer may be 10 μm to 500 um. The metal particles in the metal pore layer, that is, metal powder, may be copper powder with an average particle size of 20 μm to 300 um, forming the pore structure of 5 μm to 200 μm. The pore structure provides the vaporization core for boiling-and-heat-exchange.

In an embodiment, a metal packaging housing of the chip is disposed between the chip surface and the metal pore layer;
or,
a thermal conductive coating is disposed between the chip surface and the metal pore layer.

Each chip of the integrated circuit device may have the metal packaging housing. Spray coating process or sedimentation process may be selected to form a layer of metal powder structure with a thickness of 10 μm to 500 um on an outer surface of the metal packaging housing which is facing away from the chip, that is, to form the metal pore layer. Heat generated by the chip may be conducted to the metal pore layer through the metal packaging housing. The metal powder is the copper powder with the average particle size of 20 μm to 300 um, forming the pore structure of 5 μm to 200 μm. The pore structure provides the vaporization core for boiling-and-heat-exchange.

The chip of the integrated circuit device may not have a metal packaging housing, that is, the chip is a bare chip without a housing. A thermal conductive coating may be disposed on the chip surface firstly, and a metal pore layer is disposed on the thermal conductive coating. Heat generated by the chip may be conducted to the metal pore layer through the thermal conductive coating.

In an embodiment, the thermal conductive coating includes a metal thermal conductive coating or a non-metal thermal conductive coating.

The thermal conductive coating may be a non-metal thermal conductive coating, such as a plastic layer or the like, and may also be a metal thermal conductive coating.

Exemplarily, a plastic layer of 5 μm to 50 um is plated on the chip surface by means of injection molding or spray coating, and further, the plastic layer contains high thermal-conductive powder material. A metal powder structure with a thickness of 10 μm to 500 um is sprayed on the plastic layer to form the metal pore layer. The metal powder is the copper powder with the average particle size of 20 μm to 300 um, forming the pore structure of 5 μm to 200 μm. The pore structure provides the vaporization core for boiling-and-heat-exchange.

In an embodiment, as shown in FIG. 3, the condenser 12 includes a condenser tube 121, and an inner wall and/or an outer wall of the condenser tube 121 are provided with a rib-like protrusion.

Here, the condenser 12 may include the condenser tube 121 disposed above the liquid surface of the cooling liquid. A condensate liquid flows in the condenser tube 121.

The cooling liquid releases heat to a tube wall of the condenser tube 121 in the process of converting from the gas phase into the liquid phase. The condensate liquid flowing through the condenser tube 121 may have a relatively low temperature. The condensate liquid performs heat exchange with the tube wall of the condenser tube 121 which has a relatively high temperature, thereby reducing the temperature of the tube wall of the condenser tube 121 and improving the effect of condensing the cooling liquid.

The condensate liquid includes, but is not limited to, water, ethanol, electronic fluorinated liquid, and/or mineral oil, or the like.

The condenser tube 121 may be horizontally arranged in one or more rows. The condenser tube 121 may be arranged in an S-shape, or may be arranged in a disc shape, which is not limited herein.

The inner wall and/or the outer wall of the condenser tube 121 are provided with the rib-like protrusions. The rib-like protrusion of the inner wall may increase a surface area of the inner wall of the condenser tube 121, and improve the heat exchange efficiency between the condensate liquid and the condenser tube 121. The rib-like protrusion of the outer wall may improve a surface area of the outer wall of the condenser tube 121, and improve the heat exchange efficiency between the cooling liquid and the condenser tube 121, thereby improving the phase-change efficiency of the cooling liquid, and thereby improving the heat dissipation effect.

In an embodiment, a height of the rib-like protrusion is of 0.1 mm to 5 mm.

In an embodiment, the condenser 12 is in contact with an inner wall of a top of the housing 11.

In an embodiment, as shown in FIG. 1, the electronic apparatus further includes an external heating component 30 disposed on an external surface of the housing 11.

The external heating component 30 may include a power supply component of the electronic apparatus and/or a control board of the electronic apparatus.

Exemplarily, a top row of a plurality of rows of the condenser tubes 121 may be in direct contact with the top of the housing 11. The top of the housing 11 may be configured for placing the external heating component 30, such as the power supply component in the electronic apparatus and/or the control board of the electronic apparatus. A heating component 20 which is not suitable to be immersed in the cooling liquid, may be disposed at the top of the housing 11.

In an embodiment, the rib-like protrusions are spirally disposed on the inner wall and/or the outer wall of the condenser tube 121.

The rib-like protrusion is arranged in a spiral manner, which may further improve the surface area of the inner wall and/or the outer wall, and improve the heat exchange efficiency between the condensate liquid and the condenser tube 121, and/or between the cooling liquid and the condenser tube 121, thereby improving the phase-change efficiency of the cooling liquid, and thereby improving the heat dissipation effect.

In an embodiment, a cross section of the rib-like protrusion is V-shaped or U-shaped.

The cooling liquid in the gas phase is easier to be phase-changed into the liquid phase at a tip, therefore, the cross section of the rib-like protrusion may be set to be V-shaped or U-shaped. In this way, the phase-change efficiency of the cooling liquid at a tip of the rib-like protrusion may be promoted, thereby improving the heat dissipation effect.

In an embodiment, a condensate liquid is provided in the condenser 12, and the condenser 12 includes: a liquid inlet 1211 disposed on the housing 11 for the condensate liquid to flow in, and a liquid outlet 1212 disposed on the housing 11 for the condensate liquid to flow out;
where the liquid inlet 1211 is communicated with an external heat exchange device;
the liquid outlet 1212 is communicated with the heat exchange device.

An outer wall of the housing 11 may be provided with the liquid inlet 1211 and the liquid outlet 1212. The condensate liquid in the condenser tube 121 flows to the heat exchange device to exchange heat with the external environment. The condensate liquid may flow into the condenser tube 121 from the liquid inlet 1211 from the outside, and after completing the heat exchange in the housing 11, flow out of the liquid outlet 1212 and flow into the heat exchange device.

The heat exchange device is configured for performing heat exchange between the condensate liquid and the external environment, and reducing the temperature of the condensate liquid which flows out of the condenser tube 121, and re-flowing the cooled condensate liquid into the condenser tube 121 from the liquid inlet 1211.

Exemplarily, the heat exchange device may include a first pipe which is connected with the liquid inlet 1211, and a second pipe which is connected with the liquid outlet 1212. The heat exchange device may include a radiating fin and a radiating fan to dissipate heat of the condensate liquid which flows through the heat exchange device.

In practical application, the liquid inlet 1211 may be communicated with external cooling water, and cooling water of a temperature of 40° C. may be introduced to keep it circulating and continuously supplied. Then, the power supply is turned on and started, the matrix-arranged chipset 212 on the printed circuit board starts to calculate. Since about 99% or more of electric energy is released from the interior of the chip in a form of heat energy during the calculation of the chipset 212, the fluorinated liquid with a phase-change temperature of 51° C., produces phase-change-and-boiling at around 51° C. Since the phase-change-and-boiling belongs to efficient latent-heat-exchange, effective cooling is performed on the chipset 212. During the boiling process, a part of the fluorinated liquid is converted into vapor, the liquid surface drops slightly, but the printed circuit board is still effectively immersed. Therefore, due to phase-change-and-boiling and heat exchange, the temperature of the chipset 212 is basically maintained between 51° C. and 58° C. The bubbles which are generated from the surface of the chipset 212, float up. Since there are plastic layer and metal pore layer on the bare chip, vaporization cores of the boiling-and-heat-exchange are produced. Therefore superheat degree of boiling-and-heat-dissipation is reduced, and heat flow density of heat dissipation is increased. Meanwhile, when chips are arranged obliquely upward at an inclination angle of 20 degrees, bubbles which are generated on the surface of the lower chip, move vertically upward under the action of floatation, and when the bubbles sweep past other chips on the same printed circuit board, the proportion of the dielectric film of these chips is significantly reduced. At the same time, disturbance is generated in a rising process of bubbles, which accelerates the process of generation and separation of upper bubbles, and improves heat-transfer temperature difference and heat-transfer coefficient of modal condensation. By means of the present solution, it may be achieved that the critical heat flux density reaches 50 W/cm² to 500 W/cm².

The bubble rises to the liquid surface of the fluorinated liquid and then enters the bubble breaking section, in this case, the bubble is stressed and suddenly drops, and the bubble quickly breaks. The droplets which are generated after the bubble breaks, fall back into the fluorinated liquid under the action of gravity, and the generated vapor moves upward to the condensation section. The inner wall and the outer wall of the serpentine condenser tube 121 in the condensation section both have spiral micro-groove (corresponding to the rib-like protrusion) with an inverted V-shape. Serpentine coil (that is, condenser tube 121) is in direct contact with the vapor. The height of the spiral micro-groove may be selected from 0.1 mm to 0.5 mm, and the angle of a V-shaped opening may be selected from 30 degrees to 135 degrees. The spiral micro-groove increases the surface area of the serpentine coil. Since the cooling water of 40° C. flows in the serpentine coil, the surface temperature of the serpentine coil is relatively low, the vapor of the fluorinated liquid is condensed on the surface of the serpentine coil. Condensed liquid drops to the surface of the fluorinated liquid in the immersion section below under the action of gravity. A whole circulating process of the fluorinated liquid from liquid evaporation, bubbles generation and rising, bubble breaking, vapor condensation, to condensed liquid backflow, is completed. FIG. 6 is an axial sectional view of an exemplary section of the serpentine condenser tube 121. As shown in FIG. 6, the spiral micro-groove with a V-shape is disposed outside the serpentine condenser tube 121.

In an embodiment, the housing 11 includes a first housing and a second housing, where the first housing hermetically covers the second housing to form the accommodating cavity.

The first housing and the second housing may be sealed in a form of a sealing ring and sealant. The first housing may be a housing cover located at an upper part, and the second housing may be a housing bottom located at a lower part.

In an embodiment, the condenser 12 may be disposed in the first housing, and the heating component 20 may be disposed in the second housing, which is convenient to maintain the condenser 12 and the heating component 20 separately when the first housing and the second housing are separated.

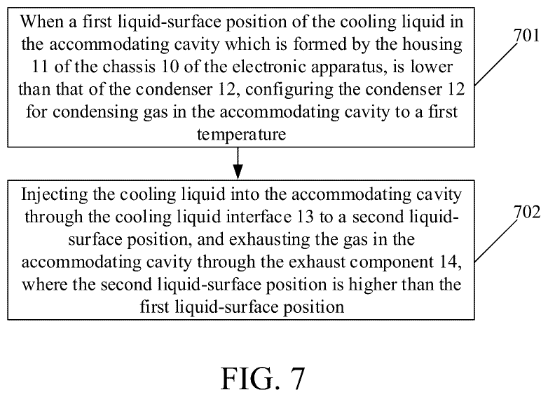

In an embodiment of the present disclosure, as shown in FIG. 7, an exhaust method for chassis 10 is provided, which is applied to the electronic apparatus shown in FIG. 1. The method includes:
step 701: when a first liquid-surface position of the cooling liquid in the accommodating cavity which is formed by the housing 11 of the chassis 10 of the electronic apparatus, is lower than that of the condenser 12, configuring the condenser 12 for condensing gas in the accommodating cavity to a first temperature;
step 702: injecting the cooling liquid into the accommodating cavity through the cooling liquid interface 13 to a second liquid-surface position, and exhausting the gas in the accommodating cavity through the exhaust component 14, where the second liquid-surface position is higher than the first liquid-surface position.

The first liquid-surface position may be a liquid-surface position to which the cooling liquid is injected into the chassis 10 when the chassis 10 is used for the first time, and may also be a liquid-surface position of the cooling liquid when the chassis 10 is in use.

In an embodiment, the first liquid-surface position is higher than that of a heating component 20.

The first liquid-surface position is higher than that of the heating component 20 in the accommodating cavity, that is, when the cooling liquid is in the first liquid-surface position, the heating component 20 is immersed in the cooling liquid.

Here, the first temperature may be lower than a phase-change temperature of the cooling liquid.

When the cooling liquid is in the first liquid-surface position, there is a space with gas above the first liquid-surface position. The gas in the space may be mixed gas of air and gas-phase cooling liquid. The condenser 12 controls gas temperature to the first temperature to condense the gas-phase cooling liquid to liquid-phase cooling liquid, thereby reducing the gas-phase cooling liquid in the mixed gas.

In an embodiment, the configuring the condenser 12 for condensing gas in the accommodating cavity to the first temperature may include: configuring the condenser 12 for condensing the gas in the accommodating cavity to the first temperature for a first predetermined duration.

If the first predetermined duration is maintained, more gas-phase cooling liquid may be condensed to liquid-phase, thereby reducing the gas-phase cooling liquid in the mixed gas. The first predetermined duration may be determined based on the amount of the gas-phase cooling liquid in the mixed gas. A relatively long first predetermined duration may be set if there is a relatively large amount of the gas-phase cooling liquid in the mixed gas. The first predetermined duration may be 5 minutes, and may also be 0.5 hours or the like.

The cooling liquid may be injected into the accommodating cavity through the cooling liquid interface 13 to raise the liquid surface of the cooling liquid to the second liquid-surface position. Since the liquid surface of the cooling liquid rises, the gas pressure in the accommodating cavity is increased, so that the gas in the accommodating cavity may be exhausted through the exhaust component 14. The exhaust component 14 may be disposed at a top of the housing 11.

In an embodiment, the second liquid-surface position is a liquid-surface position when the accommodating cavity is filled with the cooling liquid.

The higher the second liquid-surface position is, the more gas is exhausted. The second liquid-surface position is a liquid-surface position when the accommodating cavity is filled with the cooling liquid, that is, when the cooling liquid is at the second liquid-surface position, all the gas in the accommodating cavity may be exhausted.

After the gas in the accommodating cavity is exhausted, a part of the cooling liquid may be discharged to a working liquid-surface position. The working liquid-surface position may be any position lower than the condenser 12 and higher than the heating component 20, such as the first liquid-surface position. Before a part of the cooling liquid is discharged, the exhaust component 14 may be closed, in this way, when the cooling liquid is discharged, air may be reduced from entering the accommodating cavity again.

Exemplarily, when the cooling liquid is injected for the first time, the cooling liquid may be injected into the accommodating cavity through the cooling liquid interface 13 to be about 3 cm above the printed circuit board (the computing board) firstly. The serpentine coil (condenser tube 121) is communicated with the external cooling water (condensate liquid), and the cooling water of 40° C. is introduced to keep it circulating and continuously supplied, for about 5 minutes, and the temperature of the serpentine coil is basically cooled to 40° C. Then the exhaust component 14 is open, and the cooling liquid is injected into the accommodating cavity through the cooling liquid interface 13. The liquid is continuously filled, with the rising of the liquid surface, air and a small amount of vapor of the fluorinated liquid are exhausted from the exhaust component 14, until all the gas is exhausted. For example, after the fluorinated liquid flows out of an exhaust tube, the liquid filling is stopped and the exhaust component 14 is closed.

Exemplarily, during the working process of the electronic apparatus, if there is liquid overflowing due to sealing problem of the housing 11 or air contained in the fluorinated liquid, the air needs to be exhausted in the case. The specific method is: maintaining the condition that the cooling water circulates and the power supply of the printed circuit board is cut off (namely, the heating component 20 stops heating), sustaining for about 0.5 hours, so that more gas-phase cooling liquid is condensed; and in this case, the cooling liquid is injected through the cooling liquid interface 13, and the exhaust component 14 is opened to exhaust the mixed gas in the housing 11; after the accommodating cavity is filled with the fluorinated liquid, injection of the cooling liquid is stopped and the exhaust component 14 is closed; finally, a part of the fluorinated liquid is discharged from the cooling liquid interface 13 until the liquid surface reaches a position of 3 cm above the printed circuit board, and the cooling liquid interface 13 is closed. The exhaust of the remaining air is completed.

When the fluorinated liquid needs to be replaced, the fluorinated liquid needs to be regenerated, or the printed circuit board (computing board) needs to be maintained, the exhaust component 14 is kept closed, the fluorinated liquid is taken from the cooling liquid interface 13, and liquid filling is performed after the regeneration of the fluorinated liquid is completed or new fluorinated liquid is used.

The boiling-point temperature of the fluorinated liquid used above is selected according to the operating conditions and the environmental conditions. The fluorinated liquid may be selected under the conditions that the phase-change temperature of the fluorinated liquid is 47° C., 51° C., 56° C. or 61° C. at 1 atm. Since the fluorinated liquid is a reagent for cleaning circuit boards, and is non-toxic, harmless, corrosion-free, and insulating, it has a good protective effect on the electronic device.

Because the phase-change temperature of air is relatively low, it cannot perform phase-change-and-heat-transfer in a normal working state of the chassis 10, which reduces the condensation effect of the condenser 12. When the condenser 12 is working, air keeps in a gaseous state, and when the temperature rises, the pressure in the housing 11 increases, so that the phase-change temperature of the cooling liquid is increased, and the condensation effect is reduced. The increased internal pressure of the housing 11 may produce negative impact on the reliability of the components in the housing 11, and may destroy the sealing property of the housing 11.

Therefore, by exhausting as much air as possible, the condensation effect of the condenser 12 may be improved, and the effect of phase-change-and-heat-dissipation is improved, and the working stability of the electronic apparatus is improved.

In an embodiment, before the configuring the condenser 12 for condensing gas in the accommodating cavity to the first temperature, the method further includes:
heating the cooling liquid to a second temperature by configuring the heating component 20 immersed in the cooling liquid, where the second temperature is higher than the first temperature.

Before the gas is exhausted, the cooling liquid may be heated to the second temperature by the heating component, such as a computing board. Increasing the temperature of the cooling liquid may make the air dissolved in the cooling liquid overflow from the liquid-phase cooling liquid to the mixed gas, and then be exhausted from the exhaust component 14.

In an embodiment, the heating the cooling liquid to the second temperature may include: heating the cooling liquid to the second temperature for a second predetermined duration.

If the second predetermined duration is maintained, the air may continuously overflow from the cooling liquid to increase the amount of exhausted air. The second predetermined duration may be 5 minutes, and may also be 0.5 hours or the like.

In an embodiment, the second temperature is greater than or equal to a phase-change temperature of the cooling liquid.

The temperature of the cooling liquid is raised to the phase-change temperature, so that the cooling liquid is vaporized, and the vaporization of the cooling liquid may increase the overflow amount of the air dissolved in the cooling liquid, thereby exhausting more air.

In an embodiment, the method further includes:
discharging the cooling liquid from the accommodating cavity through the cooling liquid interface 13 to a third liquid-surface position, where the third liquid-surface position is lower than the second liquid-surface position and higher than the first liquid-surface position; and
injecting the cooling liquid into the accommodating cavity through the cooling liquid interface 13 to the second liquid-surface position, and exhausting the gas in the accommodating cavity through the exhaust component 14.

The cooling liquid is injected into the accommodating cavity through the cooling liquid interface 13 to the second liquid-surface position, and after the gas in the accommodating cavity is exhausted through the exhaust component 14, the cooling liquid may be discharged to the third liquid-surface position, so that a negative pressure is generated in the accommodating cavity. The air dissolved in the cooling liquid may further overflow from the cooling liquid. When the cooling liquid is injected into the accommodating cavity again to the second liquid-surface position, the overflowed air may be exhausted from the housing 11, thereby reducing the amount of air in the accommodating cavity and improving the condensation effect.

In an embodiment, the cooling liquid may be maintained at the third-surface position for a third predetermined duration.

If the third predetermined duration is maintained, the air may continuously overflow from the cooling liquid, to increase the amount of exhausted air. The third predetermined duration may be 5 minutes, and may also be 0.5 hours or the like.

The methods disclosed in several method embodiments provided by the present disclosure may be arbitrarily combined without conflicts to obtain new method embodiments.

The features disclosed in several product embodiments provided by the present disclosure may be arbitrarily combined without conflicts to obtain new product embodiments.

The features disclosed in several method or product embodiments provided by the present disclosure may be arbitrarily combined without conflicts to obtain new method embodiments or product embodiments.

Other embodiments of the present disclosure would be apparent to those skilled in the art after considering the specification and practicing the disclosure disclosed herein. The present disclosure is intended to cover any variations, uses, or adaptations of the present disclosure, these variations, uses, or adaptations follow the general principles of the present disclosure and include common knowledge or common technical means in the art which are not disclosed in the present disclosure. The specification and embodiments are regarded as exemplary only, with a true scope and spirit of the present disclosure being indicated by the following claims.

It should be understood that the present disclosure is not limited to the precise structures that have been described above and shown in the accompanying drawings, and various modifications and changes may be made without departing from the scope thereof. The scope of the present disclosure is limited only by the appended claims.

What is claimed is:

1. A chassis, comprising:
a housing, forming an accommodating cavity, wherein the accommodating cavity is configured for accommodating cooling liquid and a heating component immersed in the cooling liquid;
a condenser, disposed in the accommodating cavity and configured for condensing the cooling liquid in a gas phase;
a cooling liquid interface, disposed on the housing; and
an exhaust component, located on the housing and at least configured for exhausting gas in the accommodating cavity when the cooling liquid is injected into the accommodating cavity through the cooling liquid interface.

2. The chassis according to claim 1, wherein,
the condenser comprises a condenser tube, and an inner wall and/or an outer wall of the condenser tube are provided with a rib-like protrusion.

3. The chassis according to claim 2, wherein,
the rib-like protrusion is spirally disposed on the inner wall and/or the outer wall of the condenser tube.

4. The chassis according to claim 1, wherein,
a condensate liquid is provided in the condenser, and the condenser comprises: a liquid inlet disposed on the housing for the condensate liquid to flow in, and a liquid outlet disposed on the housing for the condensate liquid to flow out;
the liquid inlet is communicated with an external heat exchange device;
the liquid outlet is communicated with the heat exchange device.

5. An electronic apparatus, comprising:
the chassis according to claim 1;
the cooling liquid, accommodated in the accommodating cavity formed by the housing of the chassis; and
the heating component, immersed in the cooling liquid, wherein the heating component comprises at least one computing board.

6. The electronic apparatus according to claim 5, wherein,
a first surface of the computing board faces towards a top of the housing, and an angle between the first surface and a vertical direction is greater than 0 degree and less than 90 degrees, wherein the first surface is provided with an integrated circuit device which generates heat.

7. The electronic apparatus according to claim 6, wherein,
the angle between the first surface and the vertical direction is greater than or equal to 5 degrees, and less than or equal to 85 degrees.

8. The electronic apparatus according to claim 6, wherein,
a chip surface of a chip of the integrated circuit device, which is facing away from the first surface, is provided with a metal pore layer, wherein the metal pore layer comprises metal particles and pores between the metal particles.

9. The electronic apparatus according to claim 8, wherein,
a metal packaging housing of the chip is disposed between the chip surface and the metal pore layer;
or,
a thermal conductive coating is disposed between the chip surface and the metal pore layer.

10. The electronic apparatus according to claim 5, wherein, for the chassis, the condenser comprises a condenser tube, and an inner wall and/or an outer wall of the condenser tube are provided with a rib-like protrusion.

11. The electronic apparatus according to claim 10, wherein, for the chassis, the rib-like protrusion is spirally disposed on the inner wall and/or the outer wall of the condenser tube.

12. The electronic apparatus according to claim 5, wherein, for the chassis, a condensate liquid is provided in the condenser, and the condenser comprises: a liquid inlet disposed on the housing for the condensate liquid to flow in, and a liquid outlet disposed on the housing for the condensate liquid to flow out;
the liquid inlet is communicated with an external heat exchange device;
the liquid outlet is communicated with the heat exchange device.

13. A chassis exhaust method, which is applied to the electronic apparatus according to claim 5, comprising:
when a first liquid-surface position of the cooling liquid in the accommodating cavity which is formed by the housing of the chassis of the electronic apparatus, is lower than that of the condenser, configuring the condenser for condensing gas in the accommodating cavity to a first temperature; and
injecting the cooling liquid into the accommodating cavity through the cooling liquid interface to a second liquid-surface position, and exhausting the gas in the accommodating cavity through the exhaust component, wherein the second liquid-surface position is higher than the first liquid-surface position.

14. The method according to claim 13, wherein before the configuring the condenser for condensing gas in the accommodating cavity to the first temperature, the method further comprises:
heating the cooling liquid to a second temperature by configuring the heating component immersed in the cooling liquid, wherein the second temperature is higher than the first temperature.

15. The method according to claim 14, wherein the second temperature is greater than or equal to a phase-change temperature of the cooling liquid.

16. The method according to claim 13, further comprising:
discharging the cooling liquid from the accommodating cavity through the cooling liquid interface to a third liquid-surface position, wherein the third liquid-surface position is lower than the second liquid-surface position and higher than the first liquid-surface position; and
injecting the cooling liquid into the accommodating cavity through the cooling liquid interface to the second liquid-surface position, and exhausting the gas in the accommodating cavity through the exhaust component.

17. The method according to claim 13, wherein the second liquid-surface position is a liquid-surface position when the accommodating cavity is filled with the cooling liquid.

18. The method according to claim 14, wherein the second liquid-surface position is a liquid-surface position when the accommodating cavity is filled with the cooling liquid.

19. The method according to claim 15, wherein the second liquid-surface position is a liquid-surface position when the accommodating cavity is filled with the cooling liquid.

20. The method according to claim 16, wherein the second liquid-surface position is a liquid-surface position when the accommodating cavity is filled with the cooling liquid.
